(19) United States
(12) Patent Application Publication
(10) Pub. No.: US 2026/0104061 A1
(43) Pub. Date: Apr. 16, 2026

(54) PUMP

(71) Applicant: City St George's, University of London, London (GB)

(72) Inventor: Qiang ZHANG, London (GB)

(73) Assignee: City St George's, University of London, London (GB)

(21) Appl. No.: 19/108,315

(22) PCT Filed: Sep. 1, 2023
(86) PCT No.: PCT/EP2023/074024

§ 371 Date: Mar. 3, 2025

(30) Foreign Application Priority Data
Sep. 2, 2022 (GB) 2212766.6
Sep. 13, 2022 (GB) 2213355.7

(51) Int. Cl. F04D 29/58; H05K 7/20

(52) U.S. Cl. CPC F04D 29/5826; H05K 7/20272

(57) ABSTRACT

A pump (103) for a processor cooling system through which working fluid is circulated to cool a processor, the pump (103) comprising:
a processor heat exchanger (105);
a casing (107) configured to be coupled to the processor heat exchanger (105), the casing (107) comprising an inlet (113) for working fluid and an outlet (115) for working fluid, the casing (107) co-operating with the processor heat exchanger (105) to define an internal pump cavity (117) in which heat exchange can occur between the processor heat exchanger (105) and working fluid as the working fluid passes from the inlet (113) to the outlet (115);
a rotor (123) mounted for rotation within the internal pump cavity (117), and
a motor (143, 145) operable to rotate the rotor (123) in order to drive working fluid from the inlet (113) through the internal pump cavity (117) to the outlet (115);
wherein the pump (103) is configured so that, in use, the processor heat exchanger (105) lies adjacent the processor so that heat can pass from the processor to working fluid in the internal pump cavity (117) as it is driven by the rotor (123) from the inlet (113) through the internal pump cavity (117) to the outlet (115).

### FIELD

This disclosure relates, in one aspect, to a pump for a processor cooling system in which a working fluid is circulated to cool a processor. Another aspect of the disclosure relates to a processor cooling system comprising the aforementioned pump and a heat exchange system, and a further aspect of the disclosure relates to a computing resource—such as a desktop computer or a server-that has a processor and a processor cooling system of the type disclosed herein for cooling that processor.

Although the pump disclosed herein is described hereafter in the context of cooling a processor in a server, it will be appreciated that this is merely illustrative and that the teachings of this disclosure may readily be applied to the cooling of a processor in any type of computing resource.

### BACKGROUND

Computers and processors are now ubiquitous in our daily lives, and there is a concomitant need for processing capacity to increase. In the context of server farms, for example for bitcoin mining or cloud storage, the size of the building housing the servers physically limits the number of servers that can be installed inside. There are advantages to be had, therefore, if individual servers can be made to be more compact so that more servers can be accommodated in the building, or if the components within those servers can be reduced in size to allow more components to be accommodated in any one server.

Processors (which for example may be so-called central processing units (CPUs) or graphics processing units (GPUs)) in a conventional desktop computer are typically air cooled by means of a fan that draws or blows air over the processor. Higher specification processors or processors that are subject to more gruelling tasks, for example in a specialist gaming computer, tend to run hotter than processors in a conventional desktop computer and as a consequence it is not unusual for conventional air cooling to be replaced by a fluid, typically liquid, cooling system in order to avoid having to run a fan at a higher speed (which would considerably increase noise).

Fluid cooling systems typically comprise a number of components in a closed fluid loop, for example a reservoir for working fluid (for example a liquid coolant such as water), a pump for drawing or driving working fluid from the reservoir and pumping it round the cooling system, a processor heat exchanger fluidly coupled to the pump for drawing heat from the processor into the working fluid, and a heat transfer system for cooling the warmed working fluid from the processor heat exchanger before returning that (now cooler) working fluid to the reservoir.

As can be appreciated from the foregoing, such cooling systems are relatively bulky, which is problematic in the context of a server where there are typically a number of processors running concurrently that all need to be cooled. It would be advantageous if the size of the cooling system as a whole could be reduced, as that would enable more processors to be accommodated in a given server or the size of a server to be reduced.

Aspects of the present disclosure have been devised with the foregoing in mind.

### SUMMARY

One presently preferred aspect of this disclosure provides a pump for a processor cooling system through which working fluid is circulated to cool a processor, the pump comprising: a processor heat exchanger; a casing configured to be coupled to the processor heat exchanger, the casing comprising an inlet for working fluid and an outlet for working fluid, the casing co-operating with the processor heat exchanger to define an internal pump cavity in which heat exchange can occur between the processor heat exchanger and working fluid as the working fluid passes from the inlet to the outlet; a rotor mounted for rotation within the internal pump cavity, and a motor operable to rotate the rotor in order to drive working fluid through the internal pump cavity from the inlet through the internal pump cavity to the outlet; wherein the pump is configured so that, in use, the processor heat exchanger lies adjacent the processor so that heat can pass from the processor to working fluid in the internal pump cavity as it is driven by the rotor from the inlet through the internal pump cavity to the outlet.

An illustrative advantage of this arrangement is that by integrating the processor heat exchanger and pump into one component, there is no need for a separate processor heat exchanger and hence the size and complexity of any cooling system of which the pump forms part can be reduced.

Optional features of other contemplated implementations of the teachings of this disclosure are as follows:
the processor heat exchanger may abut against the processor when the pump is in use.
the casing may comprise an annular outer casing and a top plate.
the top plate may be configured to provide the inlet.
the annular outer casing may be configured to provide the outlet.
the outer casing may include a volute portion leading from said pump cavity towards said outlet.
the rotor may be supported for rotation from the top plate of the casing.
the rotor may be suspended from the top plate of the casing.
the rotor may include a central hollow portion having a generally frustroconical profile.
the diameter of said generally frustroconcial central profile preferably increases towards the processor heat exchanger.
a surface of the rotor closest to the processor heat exchanger may include a plurality of radial vanes that project from the rotor surface towards the processor heat exchanger.
the vanes may be curved.
the vanes may co-operate with a tubular mounting portion of the rotor provided within said hollow portion to provide a plurality of openings through which working fluid can flow from said inlet towards said outlet.
the top plate may include a tubular mounting portion, a pin being provided to couple the top plate mounting portion to the rotor tubular mounting portion, said pin being secured in place by means of a fastener, such as a circlip.
the processor heat exchanger may be of a material having a high coefficient of thermal conductivity, such as copper.
a surface of the processor heat exchanger facing the pump cavity may be profiled to increase the surface area of said processor heat exchanger surface.
the surface may be dimpled.
the surface may include a central nipple projecting into said pump cavity to increase the surface area of said processor heat exchanger and direct incoming working fluid radially outwardly to avoid local re-circulation of working fluid.

Another aspect of the disclosure provides a processor cooling system comprising the aforementioned pump, and a heat exchange system fluidly coupled to the pump, the arrangement being such that working fluid warmed by said processor is driven by the pump to and through the heat exchange system for heat transfer with the ambient environment, and thence from the heat exchange system back to the pump.

One illustrative advantage of this arrangement is that the number of fluid couplings within the cooling system can be reduced, and hence the danger of leaks occurring can be reduced.

In one aspect of the disclosure the heat exchange system may comprise a heat transfer system, said heat transfer system comprising a fan, and a heat exchanger arranged relative to the fan so that the fan is operable to blow or draw air over and/or through the heat exchanger, wherein the fan and the heat exchanger each include a pathway (optionally an internal pathway) through which working fluid can flow, the respective pathways being coupled to one another so that working fluid can flow through the fan and the heat exchanger to enable heat transfer between the working fluid and the air.

One illustrative advantage of this arrangement is that the area available for heat transfer is increased, relative to a conventional heat transfer system, without having to increase the footprint of the heat transfer system. Another advantage is that the efficacy of heat transfer is improved, as compared with a conventional heat transfer system, without increasing the noise generated by the fan by running it at a higher speed.

In a preferred implementation the fan comprises: a hollow axle, a hollow hub fluidly coupled to the axle so that working fluid can flow through the axle and the hub, and a plurality of blades extending radially from the hub; at least said axle being of a heat conducting material so that heat transfer can occur between working fluid flowing through said axle and the air.

Optional features of other contemplated implementations of the teachings of this disclosure are as follows:
the hollow hub and/or said blades may be of a heat conducting material;
at least one of said blades may be hollow and fluidly coupled to said hub so that working fluid can flow into and out of said hollow blade for heat transfer with the air;
one or more of said blades may include an internal blade pathway through which working fluid can flow;
said internal blade pathway may include a plurality of perturbators operable to increase perturbations in working fluid flowing through the internal blade pathway;
said internal blade pathway may be serpentine;
said blade may comprise one or more internal walls, said internal walls being configured to provide an internal blade pathway that is serpentine in one dimension within said blade;
said blade may have a leading edge and a trailing edge, and said internal blade pathway may be serpentine in one dimension that extends lengthwise between said leading edge and said trailing edge;

said blade may comprise a plurality of more internal walls, said internal walls being configured to provide an internal blade pathway that is serpentine in two dimensions within said blade;
said blade may have a leading edge, a trailing edge, and first and second sidewalls extending between said leading and trailing edges; said internal blade pathway may be serpentine in a first dimension that extends longitudinally between said leading edge and said trailing edge, and in a second dimension that extends transversely between said first and second sidewalls;
said internal blade pathway may comprise an inlet for ingress of working fluid and an outlet for egress of working fluid;
said inlet may be located in a first blade and said outlet may be located in a second blade that is radially spaced from said first blade so that said internal blade pathway extends through more than one blade;
said inlet and said outlet may be located in the same blade so that said internal blade pathway extends through a single blade;

said hub may include an internal baffle that subdivides said hollow hub into a first manifold on one side of said baffle and a second manifold on the other side of said baffle, each said manifold may include a plurality of ports at spaced locations about a peripheral wall of the hub;
said ports may enable fluid communication between said hub and the inlet and the outlet of said internal blade pathway;
a port in said first manifold may be in fluid communication with said inlet, and a port in said second manifold may be in fluid communication with said outlet;
sidewalls of one or more of said blades may be provided with a plurality of ribs;
an external surface of said hub may be provided with a plurality of ribs;
said blades may include a rip region, and the tip region of at least one of said blades may comprise a winglet;
said heat exchanger may define a recess in which at least part of said fan is located;
said fan may be enclosed within a void defined inside said heat exchanger;
said heat exchanger may comprise a fluid permeable body, said internal pathway extending through said fluid permeable body;
said internal pathway through said heat exchanger may comprise a length of piping through which working fluid can flow for heat exchange between the pipe and the air;
the heat transfer system may comprise a plurality of vanes through which said length of piping extends, said vanes being thermally coupled to said piping;
said heat exchanger may comprise a plurality of vanes and said internal pathway may comprise a serpentine pathway extending through one or more of said vanes.

A further aspect of the disclosure relates to a computing resource-such as a desktop computer or a server for example-that comprises a processor, and a processor cooling system of the type disclosed herein for cooling that processor.

Other advantages and aspects of the heat transfer system disclosed herein will be apparent from the detailed description provided below.

### BRIEF DESCRIPTION OF THE DRAWINGS

The teachings of this disclosure, and arrangements embodying those teachings, will hereafter be described by way of illustrative example with reference to the accompanying drawings, in which:

FIG. 1 is a schematic rear isometric view of a heat transfer system;

FIG. 2 is a schematic front isometric view of the heat transfer system shown in FIG. 1;

FIG. 3 is a rear elevation of the heat transfer system shown in FIGS. 1 and 2;

FIG. 4 is a cross-sectional view of the heat transfer system along the line A-A in FIG. 3;

FIG. 5 is an enlarged view of the region marked “B” in FIG. 4;

FIG. 6 is a schematic perspective view of an illustrative fan (impeller) of the heat transfer system shown in FIGS. 1 and 2;

FIG. 7 is a longitudinal (i.e. end to end) elevation in cross-section of an illustrative blade for the fan of FIG. 6;

FIG. 8 is a transverse (i.e. side to side) elevation in cross-section of the blade shown in FIG. 7;

FIG. 9 is a longitudinal (i.e. end to end) elevation in cross-section of another illustrative blade for the fan of FIG. 6;

FIG. 10 is a transverse (i.e. side to side) elevation in cross-section of the blade shown in FIG. 9;

FIG. 11 is a schematic isometric view of a pump according to an aspect of the present disclosure;

FIG. 12 is a schematic cross-sectional view along the line C-C of FIG. 11;

FIGS. 13 and 14 are, respectively, top and bottom plan views of a component of the pump shown in FIG. 11;

FIGS. 15 and 16 are, respectively, a side elevation and an isometric view of another component of the pump shown in FIG. 11;

FIG. 17 is a schematic representation of a processor cooling system;

FIG. 18 is a schematic isometric view of a processor cooling system that includes a heat transfer system of the type shown in FIGS. 1 to 10 of the drawings; and

FIG. 19 is a schematic representation of a computing resource that includes a processor and a processor cooling system of the type disclosed herein.

### DETAILED DESCRIPTION

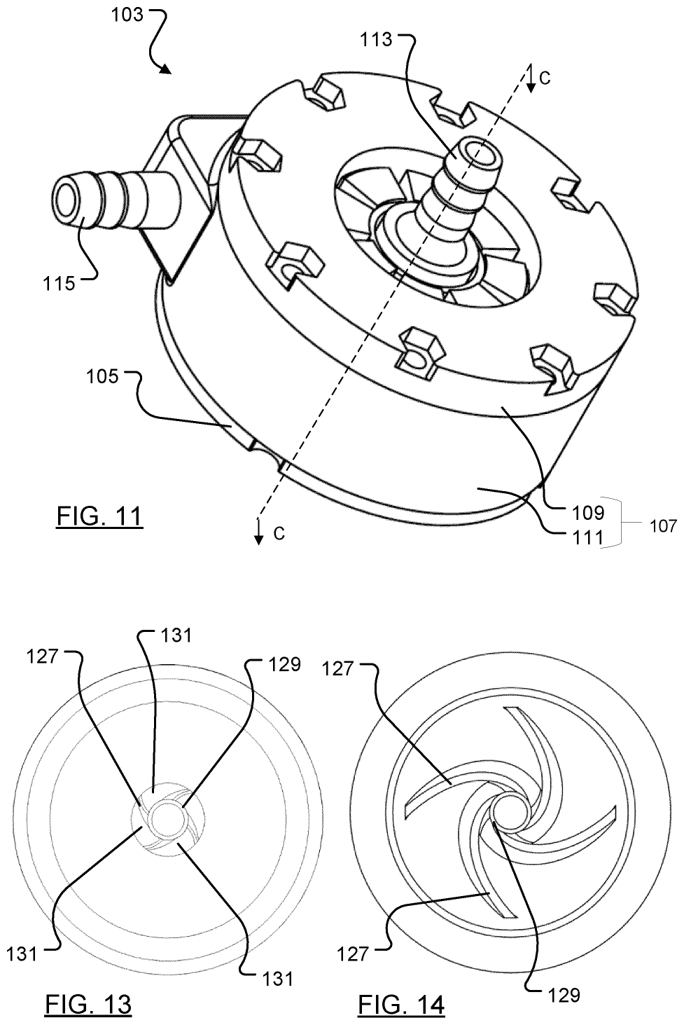

FIG. 11 is a schematic isometric view of a pump 103 embodying the teachings of the present disclosure.

The pump comprises a processor heat exchanger 105 to which a casing 107 is coupled, for example by means of a plurality of bolts, screws or other fixings (not shown). The casing 107 comprises an annular outer casing 111 and a top plate 109. An inlet 113 is provided in the top plate 109, and an outlet 115 is provided in the annular outer casing 111.

The processor heat exchanger 105 is configured to lie adjacent, in use, to a processor that is to be cooled. In a preferred arrangement the processor heat exchanger abuts against the processor in use to provide a good thermal coupling between the processor and the processor heat exchanger. Thermal paste may be provided between the processor and the processor heat exchanger to enhance the thermal coupling between the processor and the processor heat exchanger. In the preferred arrangement, the processor heat exchanger is of a material having a high coefficient of thermal conductivity, such as copper.

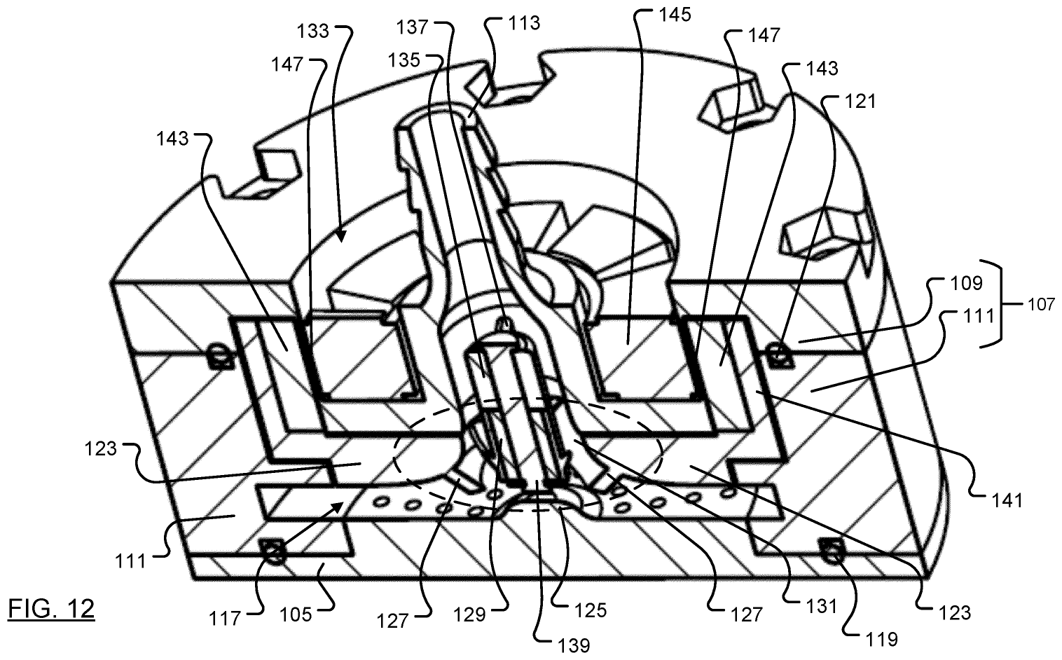

FIG. 12 is a cross-sectional view through the pump 103 along the line C-C in FIG. 11. As shown in FIG. 12, the casing 107 co-operates with the processor heat exchanger 105 to define an internal pump cavity 117. O-rings 119, 121 provide seals between the processor heat exchanger 105 and the annular outer casing 107, and between the annular outer casing 107 and the top plate 109.

A rotor 123 is mounted for rotation within the internal pump cavity 117. A central part of the rotor 123 includes a hollow portion 125 with a generally frustoconical internal profile. Referring additionally to FIGS. 13 and 14, a plurality of radial vanes 127 project into the internal pump cavity 117 from a surface of the rotor that is closest to the processor heat exchanger 105.

The radial vanes 127 function to stir and pump working fluid from the inlet 113 towards the outlet 115 as the rotor rotates. In the preferred arrangement, the vanes are curved and spiral radially outwardly from a central part of the rotor. The radial vanes are coupled at their respective radially innermost points to a tubular mounting portion 129 of the rotor that is provided within said hollow portion 125. The vanes co-operate with the tubular mounting portion 129 to provide a plurality of openings 131 between the tubular mounting portion and the frustoconical profiled part of the rotor. Working fluid can flow, in use, from the inlet 113 through the openings 131 into the internal pump cavity 117, and onwards towards the outlet 115.

As shown in FIG. 12, the top plate 109 includes an annular recess 133 surrounding the inlet 113. A wall of the top plate 109 that defines the inlet 113 expands to provide an internal chamber in which a tubular mounting portion 135 is provided. The top plate tubular mounting portion 135 is coupled to the top plate by means of a plurality of ribs 137. A pin 139 extends through the top plate tubular mounting portion 135 and the rotor tubular mounting portion 129 to couple the rotor 123 to the top plate 109 in such a way that the rotor can rotate relative to the top plate 109. A circlip or other fastener is coupled to the pin 139 to keep the rotor and top plate together.

As will be appreciated by persons skilled in the art, by virtue of this arrangement the rotor is supported for rotation from the top plate of the casing, more specifically by being suspended from the top plate of the casing.

The rotor 123 includes an annular peripheral skirt 141 extending towards the top plate 109. A ring of magnets 143 are coupled to an internal surface of the skirt 141. The magnets 143 co-operate with a stator 145 through a peripheral wall 147 of the top plate recess 133 to provide a motor that, when energised, causes the rotor to spin. The motor may comprise, for example. a frameless brushless DC motor of the type sold by Stock Drive Products/Sterling Instrument (see: http//www.sdp-si.com/).

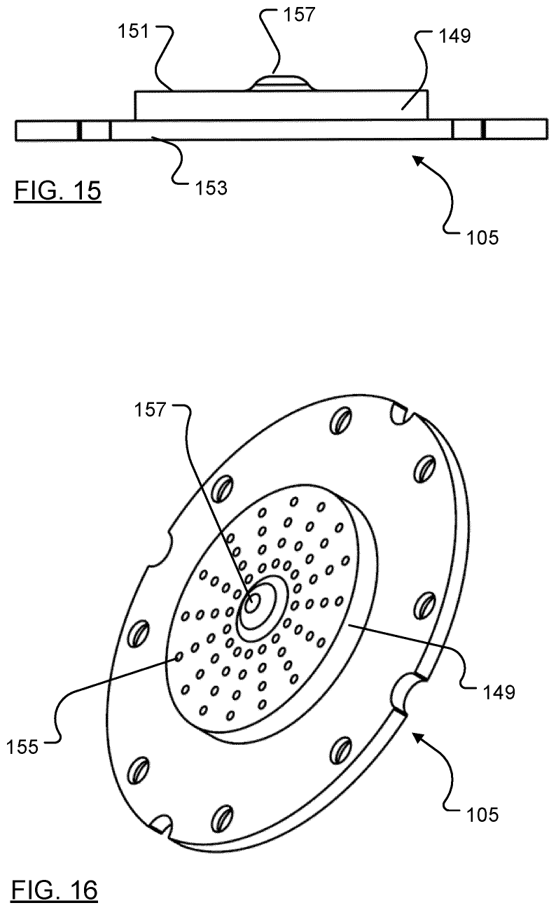

Referring now to FIGS. 14 and 15, the processor heat exchanger 105 comprises a thickened central portion 149 that will lie adjacent the processor when the pump is in use. An external face 151 of the thickened central portion 149 furthest from a surface 153 that will abut against the processor in use is profiled to increase the surface area of the processor heat exchanger 105 that faces the working fluid flowing through the internal pump cavity 117. The profiled external face also introduces perturbations into the flow of working fluid which enhances mixing of the working fluid and heat transfer. In this particular arrangement, the external face is profiled by means of a plurality of dimples 155.

The thickened central portion 149 also includes a raised central nipple 157 that will lie opposite the pin 139 and project into the internal pump cavity 117 when the pump is assembled. The nipple 157 increases the surface area of the processor heat exchanger and drives working fluid from the inlet radially outwardly towards the outlet, thereby discouraging the establishment of a local dead zone where the working fluid re-circulates instead of flowing to the outlet.

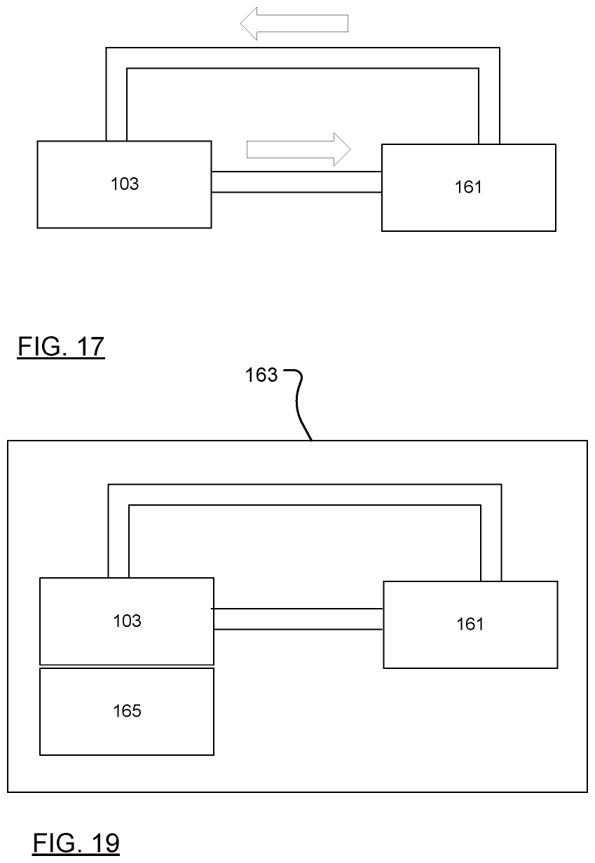

Referring now to FIG. 17, the pump 103 disclosed herein is of utility in a processor cooling system 159. As shown, the pump 103 is fluidly coupled to a heat exchange system 161 so that working fluid can flow from the pump 103 to the heat exchange system 161, and thence from the heat exchange system 161 back to the pump. The heat exchange system may comprise a radiator, and optionally a fan arrangement configured to drive ambient air over the radiator to enhance heat exchange between the working fluid and the ambient air.

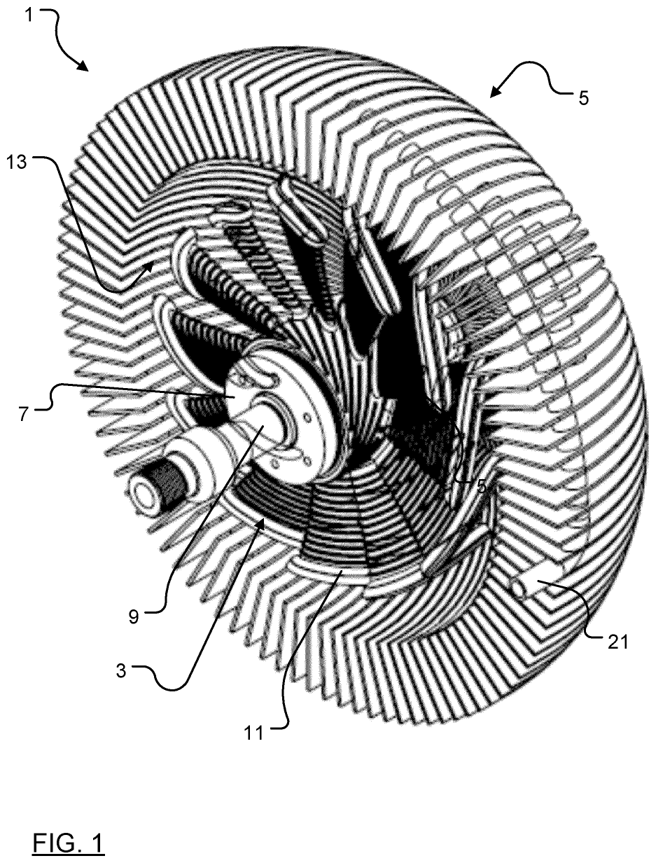

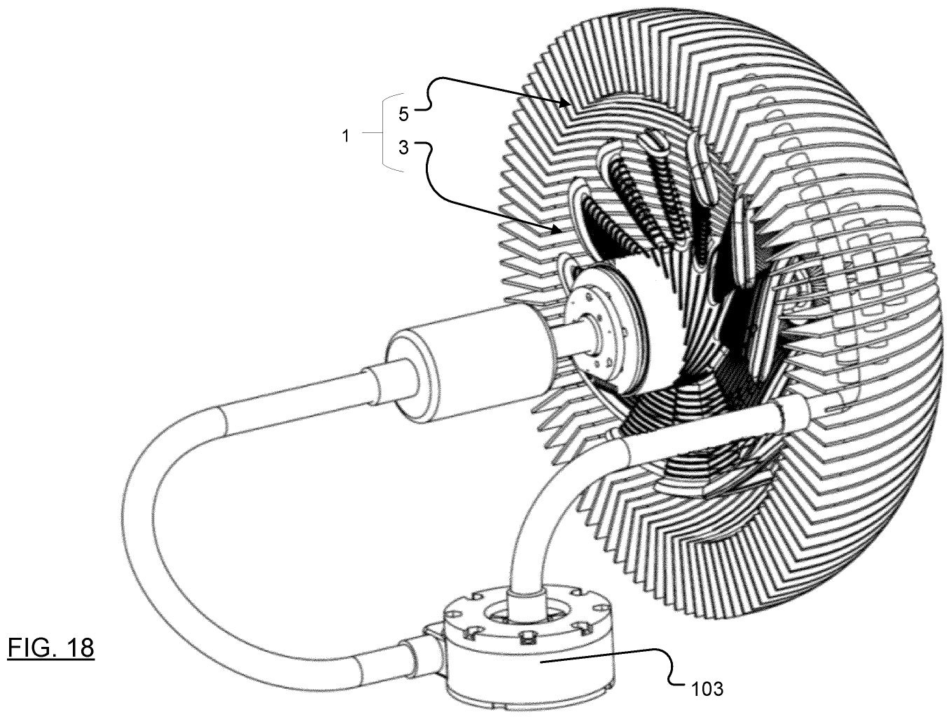

In a particularly preferred arrangement, depicted schematically in FIG. 18, the heat exchange system 161 may comprise a heat transfer system 1 of the type shown in FIGS. 1 to 10 of the accompanying drawings, which system includes a fan 3 and a heat exchanger 5. This heat transfer system is highly efficient and particularly compact, and as such would be ideal for a processor cooling system.

As shown in FIG. 19, the pump 103 may be installed adjacent a processor 165 of a computing resource 163, such as a desktop computer or a server, and fluidly coupled to a heat exchange system 161 so that the pump can draw heat from the processor 165 into the working fluid and then lose that heat by means of the heat exchange system, before the working fluid is returned to the pump.

Referring now to FIGS. 1 to 3 of the accompanying drawings, the heat transfer system 1 mentioned above comprises a fan 3 and a heat exchanger 5. The fan 3 comprises a hub 7 that is coupled to an axle 9 (one end of which is visible) for rotation therewith. A plurality of blades 11 extend radially outwardly from the hub 7.

In this particular arrangement the heat exchanger 5 is generally bowl-shaped and defines a recess 13 within which the hub 7 and blades 11 of the fan 3 lie. This arrangement is advantageously particularly compact as the heat exchanger doubles up as a safety shield by obstructing access to the fan when the heat exchanger is coupled to a support surface (such as a cabinet housing other components of a computing resource, for example). Whilst this arrangement has advantages, it will be appreciated that it is not essential for the heat exchanger to be bowl-shaped or, indeed, for the fan to be within a void defined by the heat exchanger. In an alternative arrangement the heat exchanger could comprise a rectangular cuboid or cuboid body that the fan is arranged to draw or blow air through and/or over.

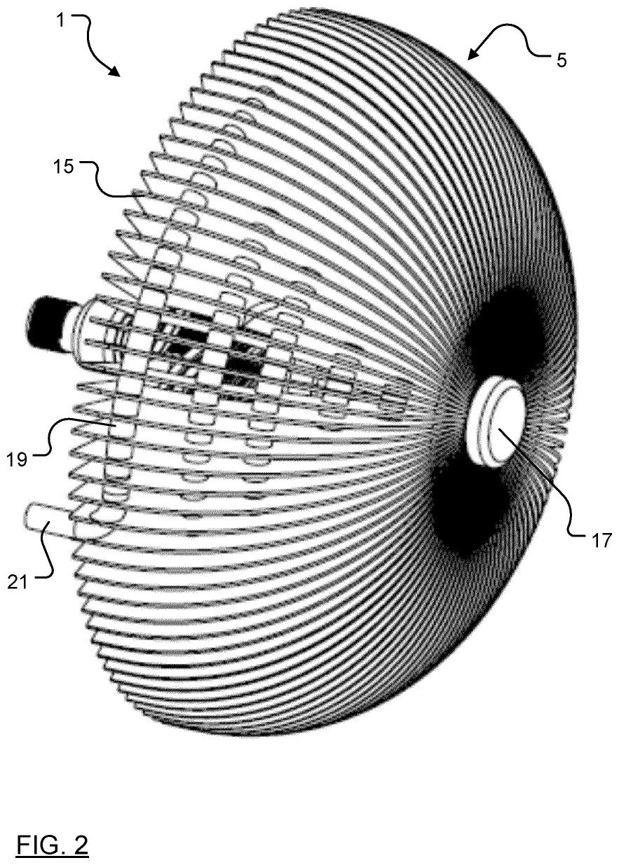

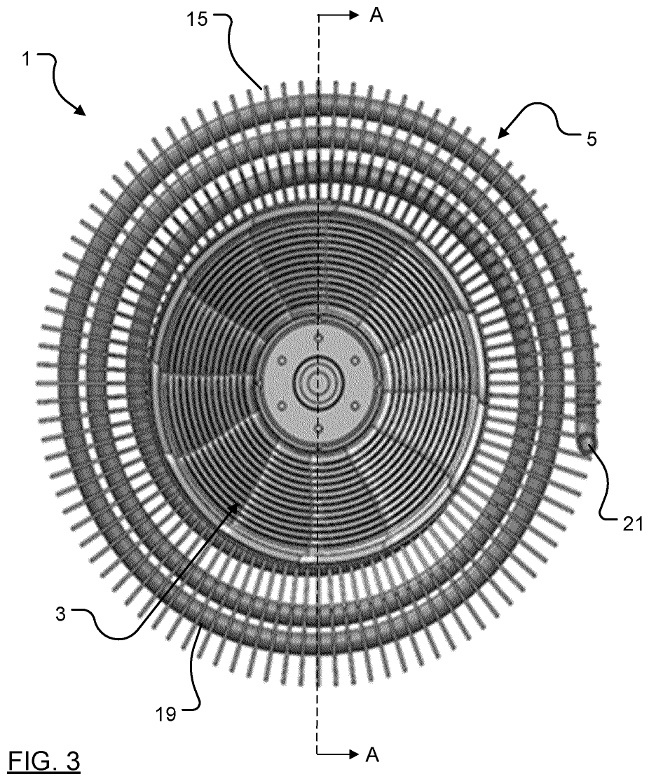

The heat exchanger 5 comprises a plurality of vanes 15 of heat conductive material that extend radially outwardly from a cap 17 (FIG. 2). In this arrangement, the vanes are each provided with a plurality of apertures 19 (best shown in FIG. 4) that co-operate to define a coiled internal passageway through the heat exchanger towards the cap 17. A coiled pipe 21 (best shown in FIG. 3 where the pipe has been shaded so that it can be seen more clearly) of heat conductive material extends from a port 23 through the coiled passageway towards the cap 17, and is closely coupled to each of the vanes for heat transfer between the pipe and the vanes. The pipe 19, as will be immediately apparent to persons of skill in the art, provides the heat exchanger with an internal fluid pathway through which a working fluid can flow.

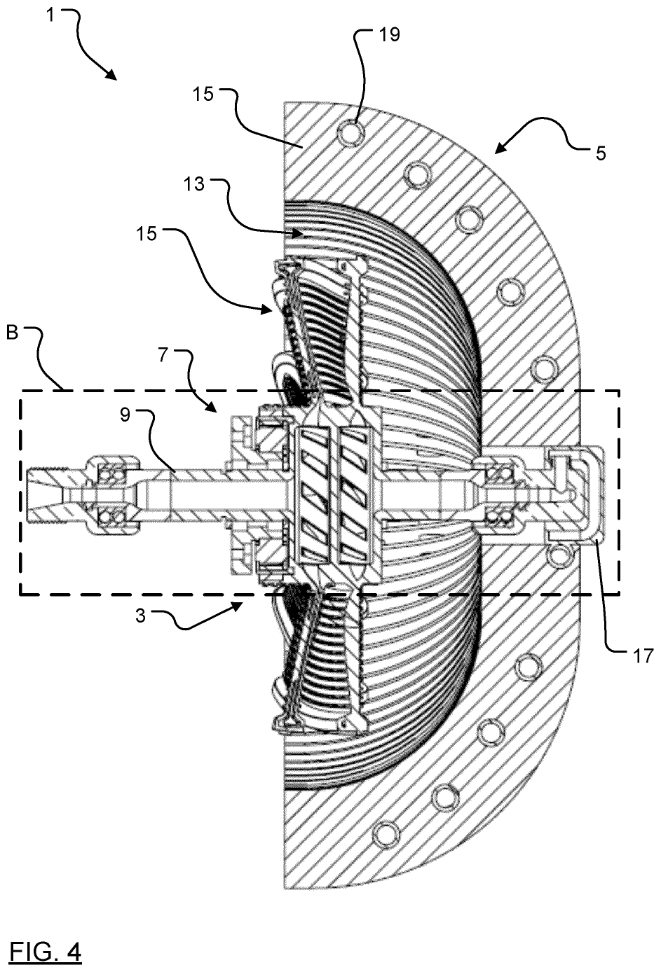

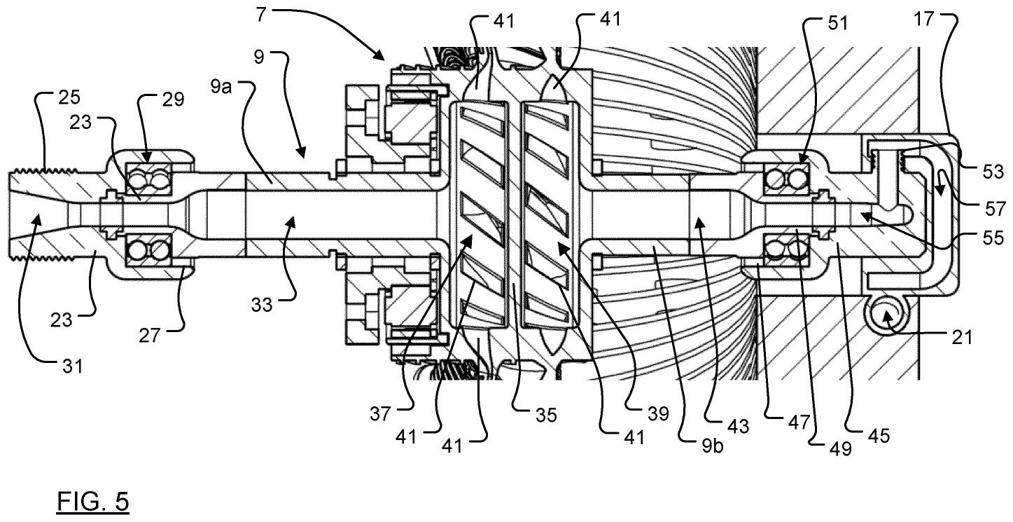

FIG. 5 shows an enlarged view of the area labelled “B” in FIG. 4. As shown in FIG. 5, a heat transfer system support 23 includes an outwardly threaded tail 25 so that the heat transfer system support 23 can be securely engaged with a support surface (not shown) such as a wall of a cabinet in which at least part of the heat transfer system is located. The heat transfer system support 23 has an enlarged open end that defines a recess 27 in which a reduced diameter portion 23 of a first part 9a of the axle 9 is received. A bearing 29 is provided between the heat transfer system support 23 and the reduced diameter portion 23 of the axle 9 so that the axle can rotate relative to the heat transfer system support 23. The heat transfer system support 23 includes a bore 31 that is in fluid communication with an internal bore 33 of the axle 9.

The hub 7 includes an internal baffle 35 that co-operates with the remainder of the hub to define a void that functions as a first fluid manifold 37 and a void that functions as a second fluid manifold 39 within the hub 7. Each manifold includes a plurality of ports 41 that are in fluid communication with serpentine internal pathways provided inside of the blades 11.

In one envisaged arrangement, each port of the first and second manifolds are in fluid communication with only one of the blades 11 so that a given port in one of the first and second manifolds provides an entrance to the serpentine fluid pathway of a blade for the ingress of working fluid, and a corresponding port in the other of the first and second manifolds provides an exit from the serpentine fluid pathway of that blade for the egress of working fluid.

In one implementation, working fluid enters the heat transfer system via the support 23 and flows via the axle 9 to the first fluid manifold 37, and thence from the first fluid manifold into the blades 11. Working fluid circulates through the serpentine internal pathways provided within the blades before exiting the blades and flowing into the second fluid manifold 39. In this configuration, with the fan rotating in a clockwise direction, fluid in the first fluid manifold is at a higher pressure than fluid in the second fluid manifold and components to the left of the baffle 35 (as shown in FIG. 5) are hence said to be on the “pressure” side of the system, whereas components to the right of the baffle 35 (again, as shown in FIG. 5) are said to be on the “suction” side of the system. If the fan were to be run in the opposite direction, then the “pressure” and “suction” sides of the system would be reversed.

Referring again to FIG. 5, the second fluid manifold is in fluid communication with an internal bore 43 of a second part 9b of the axle 9. The cap 17 co-operates with a fan support 45 that has an enlarged open end which defines a recess 47 in which a reduced diameter portion 49 of the second part 9b of the axle 9 is received. A bearing 51 is provided between the fan support 45 and the reduced diameter portion 49 of the axle 9 so that the axle can rotate relative to the fan support 45.

The fan support 45 includes a port 53 that is in fluid communication with an internal bore 55 within the fan support 45. The port 53 opens to an internal void 57 within the cap 17, and the cap internal void 17 is in fluid communication with the pipe 21 passing through the apertures 19 in the vanes 11 of the heat exchanger 5.

As will be appreciated by persons skilled in the art, working fluid entering the heat transfer system support can flow through the first part of the axle, and thence through the blades of the fan. This allows the fan blades to assist in the transfer of heat between the working fluid and the ambient air. Once the working fluid has passed through the blades, it can then pass via the other part of the axle and the fan support to the coiled pipe that is in thermal contact with the vanes of the heat exchanger, and heat can be exchanged between the working fluid and the ambient air as the fluid moves through the pipe towards port 23.

By virtue of this arrangement heat exchange can take place between the vanes of the heat exchanger and the blades of the fan (and optionally between other components of the fan), thereby improving heat exchange as compared with a conventional heat transfer system where heat exchange only occurs between the evaporator and the ambient air. Specifically, in the arrangements disclosed herein fan blade tip leakage flow, hub secondary flow, and other separated flows near the blade surfaces can all contribute to the enhancement of heat transfer. Advantageously, this improvement is provided without having increase the operating noise by running the fan at a higher speed than a conventional heat transfer system.

Referring now to FIG. 6 of the drawings, in one envisaged implementation the blades 11 of the fan have an aerofoil shape so that the ambient air is effectively accelerated towards the heat exchanger. It is also envisaged to provide one or more of the blades (or in this particular example, all of the blades) with a plurality of ribs 59 that project outwardly from the outer surface of the blade. The ribs 59, if provided, provide a number of benefits. In the first instance, the ribs 59 provide an aerodynamic benefit by aligning the main flow direction and reducing secondary flow. The ribs also increase the area available for heat transfer, and act as turbulators which enhance the local heat transfer rate.

As depicted in FIG. 6, an external surface of the hub 7 may alternatively or additionally be provided with ribs 61 that enhance the capabilities of the heat transfer system in the same way as the ribs 59 on the blades, for example by enhancing horseshoe vortex flow structures near the hub.

In one implementation it is proposed to provide tips 63 of the blades with winglets 65 that provide an aerodynamic benefit by reducing leakage flow around the fan. The winglets 65 also increase the area available for local heat transfer, and may be provided as well as or instead of the ribs on the blades and/or the hub. An implementation with winglets provides significant heat transfer benefits as tip leakage flow offers the highest velocity magnitude as well as three dimensional vortical turbulent flow structures.

It is also envisaged for the hub, and optionally the axle, to be manufactured from a heat conductive material. In a particularly advantageous implementation, additive fabrication methods may be employed to manufacture some or all of the components of the fan, and some or all of the heat exchanger 5. In one envisaged implementation, the heat conductive material may comprise a metal or metal alloy, but it will be appreciated by persons skilled in the art that benefits may accrue by manufacturing at least the axle of the fan from any material that heats up when it comes into contact with a (relatively) warmer working fluid, and as a consequence “heat conductive material” should be construed accordingly.

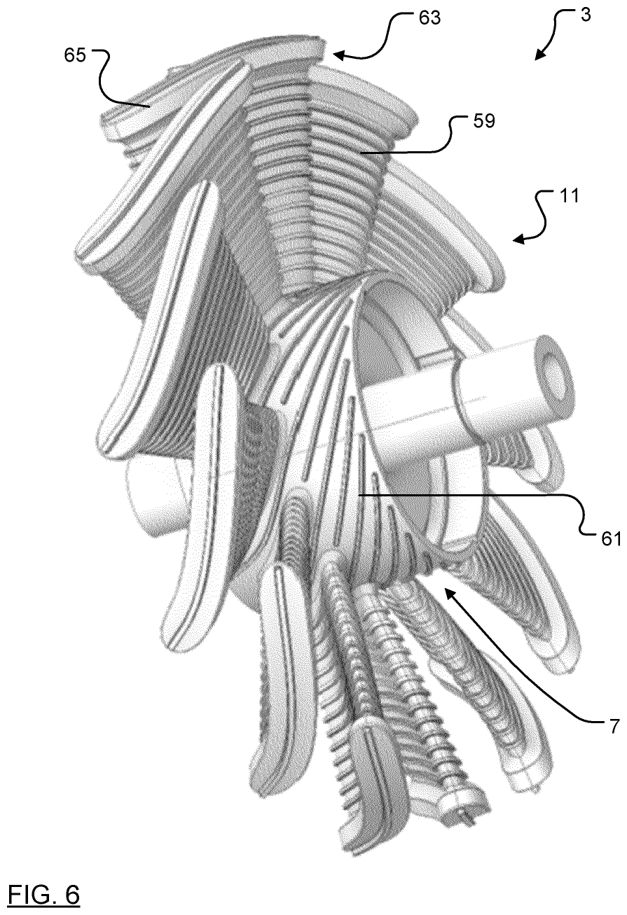

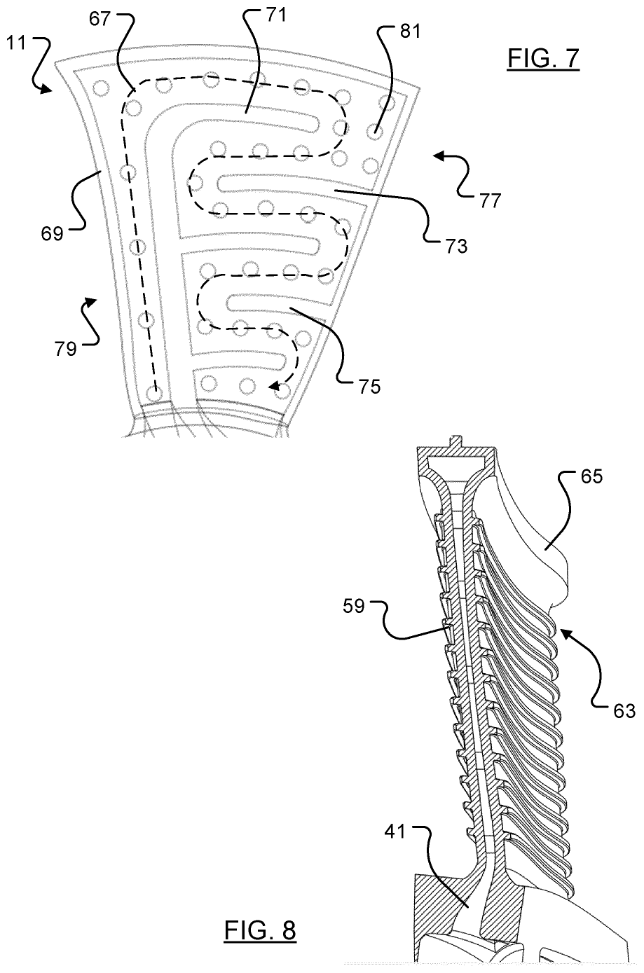

FIG. 7 is a longitudinal (i.e. end to end) elevation in cross-section of an illustrative blade for the fan of FIG. 6, and FIG. 8 is a transverse (i.e. side to side) elevation in cross-section of the blade shown in FIG. 7.

As mentioned above, the ports 41 in the first and second fluid manifolds 37,39 provide access to a serpentine internal pathway 67 within the blades 11 of the fan 3. The serpentine internal pathway is defined by an external peripheral wall 69 of the blade 11, a generally E-shaped internal wall 71, and two internal walls 73 and 75 that extend between the walls of the E-shaped internal wall 71 from a part of the external wall 69 that forms a trailing edge 77 of the blade 11 towards a part of the external wall 69 that forms a leading edge 79 of the blade 11. Advantageously, this configuration of serpentine internal pathway guides working fluid through the leading edge 79 and tip region 63 of the blade where the rate of heat transfer between the working fluid and the ambient environment is high.

The blade may also be provided with a plurality of pegs 81 that span the serpentine internal pathway 67 in a transverse direction and are coupled to each sidewall of the blade. The pegs 81 function to strengthen the blade (particularly if the blade is formed by means of an additive manufacturing process) and also as perturbators which are capable of introducing perturbations to the working fluid flowing through the pathway, which perturbations help to increase the local rate of heat transfer between the working fluid and the ambient environment. Other types of perturbators, such as pegs or other features extending partway into the internal pathway may alternatively or additionally be provided.

It will be appreciated that the provision of serpentine pathways through the blades greatly increases the area available for heat transfer between the working fluid and the ambient environment. In a preferred arrangement the ports are arranged so that fluid passes into and out of all of the blades at the same time, as this tends to balance the weight of fluid flowing through the fan. In other contemplated arrangements, a serpentine fluid pathway may be provided that extends through more than one blade with an entrance in one fan blade and an exit in another adjacent or more circumferentially distant fan blade.

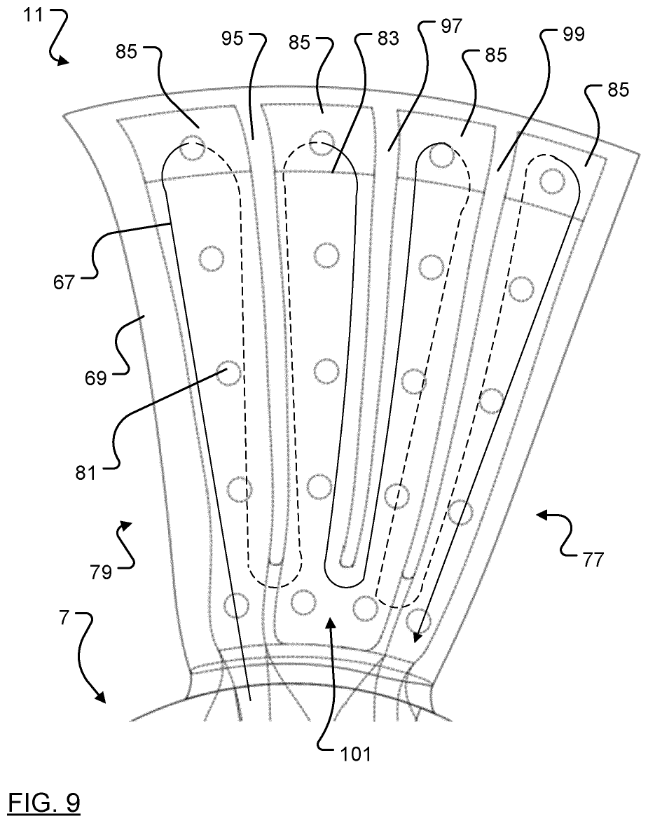

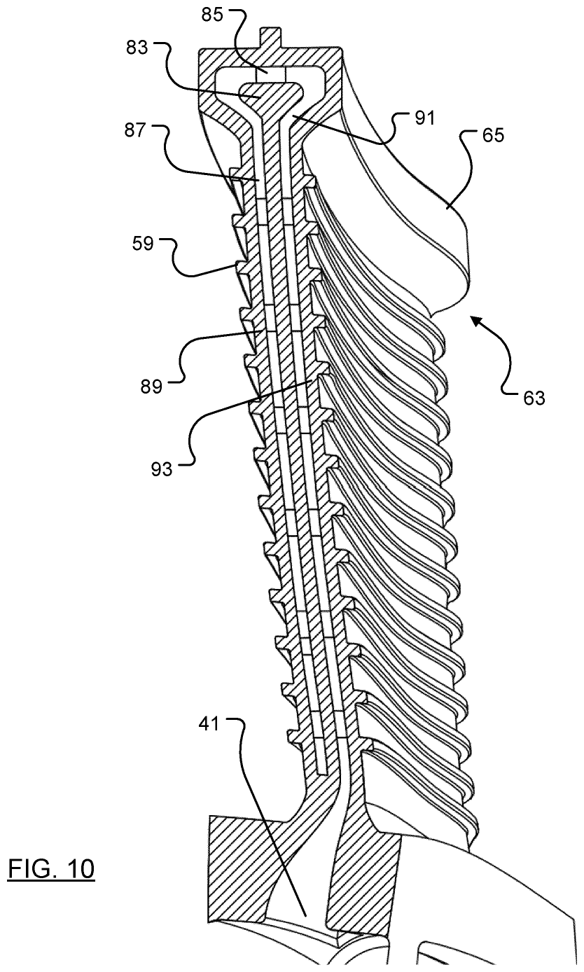

Referring now to FIGS. 9 and 10, FIG. 9 is a longitudinal (i.e. end to end) elevation in cross-section of another illustrative blade for the fan of FIG. 6 and FIG. 10 is a transverse (i.e. side to side) elevation in cross-section of the blade shown in FIG. 9. For brevity, features common to the blade shown in FIGS. 7 and 8 and the blade shown in FIGS. 9 and 10 are designated with the same reference numerals and will not be described again.

As can best be appreciated from FIG. 10, the blade 11 further comprises an longitudinal internal wall 83 running between the external peripheral walls 69 of the blade from the leading edge 79 to the trailing edge 77. As is best shown in FIG. 10, the internal wall 83 stops short of a top wall of the winglet 65 at spaced locations within the blade to provide passageways 85 for working fluid flow in a transverse direction between voids 87 defined between the internal wall 83 and a first sidewall 89 of the blade and voids 91 defined between the internal wall 83 and a second sidewall 93 of the blade.

In addition, to permit working fluid flow in a longitudinal direction the blade further comprises a plurality of transverse walls 95, 97 and 99 (FIG. 9) that are cut away sequentially to either side of the longitudinal internal wall 83 towards the hub 7. In the particular example shown in FIG. 9 and looking from the trailing edge 77 towards the leading edge 79, transverse wall 95 is cut-away on the right side of the longitudinal internal wall 83 (the cut-away portion being obscured in FIG. 9), transverse wall 97 is cut-away 101 on the left hand side of the longitudinal internal wall 83 (and hence is visible in FIG. 9), and transverse wall 99 is cut-away on the right hand side of the longitudinal internal wall 83 (and is again obscured in FIG. 9).

In the particular example shown in FIG. 9, and again looking from the trailing edge 77 of the blade towards the leading edge 79, working fluid can flow up the inside of the leading edge 79 on the left hand side of wall 83 through a void defined by the leading edge and transverse wall 95, over the top of wall 83, down the inside of the leading edge on the right hand side of wall 83 (shown by a dashed line) through a void defined by the leading edge and transverse wall 95, up into a void formed between transverse walls 95 and 97 on the right hand side of wall 83 (again shown by a dashed line), over the top of wall 83, down into a void formed between transverse walls 95 and 97 on the left hand side of wall 83, up into a void formed between transverse walls 97 and 99 on the left hand side of wall 83, over the top of wall 83, down into a void formed between transverse walls 97 and 99 on the right hand side of wall 83 (shown by a dashed line), up into a void formed between transverse wall 99 and the trailing edge 77 on the right hand side of wall 83 (again shown by a dashed line), over the top of wall 83, and into a void defined by transverse wall 99 and the trailing edge 77.

In summary, the principal difference between the blade shown in FIGS. 7 and 8 and the blade shown in FIGS. 9 and 10 is that in the FIG. 7 blade the serpentine internal pathway extends in one dimension (namely, back and forth longitudinally along the length of the blade), whereas in the FIG. 9 blade the serpentine internal pathway extends in two dimensions (namely, back and forth longitudinally along the length of the blade and transversely from side to side of the blade).

It will be apparent to persons skilled in the art from the foregoing that the heat transfer system herein disclosed provides a greater surface area for heat exchange than a conventional impeller and evaporator arrangement, which enables improvements in the efficiency of heat transfer. A number of additional improvements and advantages have been disclosed above. For example, whilst in conventional systems the fan merely propels air over the adjacent evaporator, the teachings of this disclosure provide skilled persons with greater design freedom, for example to enhance fan performance in terms of aerodynamics and/or heat transfer.

It will be appreciated that whilst various aspects and embodiments of the present disclosure have heretofore been described, the scope of the disclosure is not limited to the particular arrangements set out herein and instead extends to encompass all arrangements, and modifications and alterations thereto, which fall within the scope of the appended claims.

In another envisaged implementation, the potential for heat transfer may be enhanced, as compared with a conventional system, simply by providing a fan with a hollow axle, a hollow hub and solid blades, where the axle and hub (optionally just the axle, and optionally the blades in addition to the axle and hub) are fabricated from a heat conducting material so that heat transfer can occur in the fan as well as in the heat exchanger. In yet another envisaged implementation, one or more of (optionally, all of) the blades may not include a serpentine internal pathway but may instead simply be hollow bodies fluidly coupled to the hub so that working fluid can flow into and out of them for heat transfer with the ambient environment.

It will also be appreciated that the fluid pathway through the heat exchanger need not necessarily be provided by a pipe. The vanes could, in another implementation, be provided with an internal serpentine pathway (similar to that disclosed above for the blades). It is also envisaged that instead of a vaned heat exchanger, the system may employ a porous body (for example, something akin to a wire wool structure) as the heat exchanger, and/or for the heat exchanger to completely surround the fan.

It should also be remembered that the foregoing internal working fluid pathways for the blades are only illustrative, and that other pathway configurations may be adopted if desired. For example, the internal wall 71 does not necessarily have to be E-shaped, as it could be configured to provide a longer and/or more serpentine or otherwise tortuous working fluid pathway.

It should also be noted that whilst the accompanying claims set out particular combinations of features described herein, the scope of the disclosure is not limited to the particular combinations hereafter claimed, but instead extends to encompass any combination of features herein disclosed. This application claims priority from co-pending UK Patent Application no. 2212766.6, the contents of which are incorporated herein by reference as though that application were included in this application in its'entirety.

Finally, it should be noted that any element in a claim that does not explicitly state “means for” performing a specified function, or “steps for” performing a specific function, is not to be interpreted as a “means” or “step” clause as specified in 35 U.S.C. Sec. 112, par. 6. In particular, any use of “step of” in the claims appended hereto is not intended to invoke the provisions of 35 U.S.C. Sec. 112, par. 6.

1-31. (canceled)

32. A pump for a processor cooling system through which working fluid is circulated to cool a processor, the pump comprising:
a processor heat exchanger;
a casing configured to be coupled to the processor heat exchanger, the casing comprising an inlet for the working fluid and an outlet for the working fluid, the casing co-operating with the processor heat exchanger to define an internal pump cavity in which heat exchange can occur between the processor heat exchanger and the working fluid as the working fluid passes from the inlet to the outlet;
a rotor mounted for rotation within the internal pump cavity, and
a motor operable to rotate the rotor in order to drive the working fluid through the internal pump cavity from the inlet through the internal pump cavity to the outlet;
wherein the pump is configured so that, in use, the processor heat exchanger lies adjacent, and abuts against, the processor so that heat can pass from the processor to the working fluid in the internal pump cavity as the working fluid is driven by the rotor from the inlet through the internal pump cavity towards the outlet.

33. A pump according to claim 32, wherein the casing comprises an annular outer casing and a top plate, said top plate being configured to provide the inlet.

34. A pump according to claim 33, wherein the annular outer casing is configured to provide the outlet, and the outer casing includes a volute portion leading from said pump cavity towards said outlet.

35. A pump according to claim 33, wherein the rotor is suspended from the top plate of the casing for rotation.

36. A pump according to claim 32, wherein the rotor includes a hollow portion having a generally frustroconical internal profile, a diameter of said generally frustroconical internal profile increasing towards the processor heat exchanger.

37. A pump according to claim 36, wherein a surface of the rotor closest to the processor heat exchanger includes a plurality of radial vanes that project from the rotor surface towards the processor heat exchanger, said vanes co-operating with a tubular mounting portion of the rotor provided within said hollow portion to provide a plurality of openings through which the working fluid can flow from said inlet towards said outlet.

38. A pump according to claim 32, wherein a surface of the processor heat exchanger facing the pump cavity is profiled to increase an area of the surface of said processor heat exchanger surface, said processor heat exchanger surface including a central nipple projecting into said pump cavity to increase the surface area of said processor heat exchanger and direct incoming working fluid radially outwardly to avoid local re-circulation of the incoming working fluid.

39. A processor cooling system comprising a pump according to claim 32 in combination with a heat exchange system that is fluidly coupled to the pump, the processor cooling system being arranged such that the working fluid warmed by said processor is driven by the pump to and through the heat exchange system for heat transfer with an ambient environment, and thence from the heat exchange system back to the pump.

40. A processor cooling system according to claim 39, wherein said heat exchange system comprises a heat transfer system, said heat transfer system comprising a fan, and a heat exchanger arranged relative to the fan so that the fan is operable to blow or draw air over and/or through the heat exchanger, wherein the fan and the heat exchanger each include a pathway through which the working fluid can flow, the respective pathways being coupled to one another so that the working fluid can flow through the fan and the heat exchanger to enable heat transfer between the working fluid and ambient air.

41. A processor cooling system according to claim 40, wherein the fan comprises a hollow axle, a hollow hub fluidly coupled to the axle so that the working fluid can flow through the axle and the hub, and a plurality of blades extending radially from the hub; at least said axle being of a heat conducting material so that heat transfer can occur between the working fluid flowing through said axle and the air.

42. A processor cooling system according to claim 41, wherein one or more of said blades includes an internal blade pathway through which the working fluid can flow, said internal blade pathway being serpentine and including a plurality of perturbators operable to increase perturbations in the working fluid flowing through the internal blade pathway.

43. A processor cooling system according to claim 42, wherein at least one of said blades comprises a plurality of internal walls, said internal walls being configured to provide an internal blade pathway that comprises either (a) serpentine in one dimension within said blade, or (b) serpentine in two dimensions within the at least one said blade.

44. A processor cooling system according to claim 43, wherein said internal blade pathway comprises an inlet for ingress of the working fluid and an outlet for egress of the working fluid; and wherein either:
(a) said inlet is located in a first blade and said outlet is located in a second blade that is radially spaced from said first blade so that said internal blade pathway extends through more than one blade; or
(b) said inlet and said outlet are located in one said blade so that said internal blade pathway extends through a single blade.

45. A processor cooling system according to claim 44, wherein said hub includes an internal baffle that subdivides said hollow hub into a first manifold on one side of said baffle and a second manifold on another side of said baffle, each said manifold including a plurality of ports at spaced locations about a peripheral wall of the hub, wherein said ports enable fluid communication between said hub and the inlet and the outlet of said internal blade pathway.

46. A processor cooling system according to claim 45, wherein a port in said first manifold is in fluid communication with said inlet and a port in said second manifold is in fluid communication with said outlet.

47. A processor cooling system according to claim 46, wherein said heat exchanger defines a recess in which at least part of said fan is located, wherein said heat exchanger comprises a fluid permeable body, and said internal blade pathway extends through said fluid permeable body.

48. A processor cooling system according to claim 47, wherein said internal blade pathway through said heat exchanger comprises a length of piping through which the working fluid can flow for heat exchange between the pipe and the air, the heat exchanger further comprising a plurality of vanes through which said length of piping extends, said vanes being thermally coupled to said piping.

49. A processor cooling system according to claim 48, wherein said heat exchanger comprises a plurality of vanes and said internal blade pathway comprises a serpentine pathway extending through one or more of said vanes.

50. A processor cooling system comprising a pump, and a heat exchange system fluidly coupled to the pump, the processor cooling system being arranged such that working fluid warmed by a processor is driven by the pump to and through the heat exchange system for heat transfer with an ambient environment, and thence from the heat exchange system back to the pump, wherein:
said pump comprises:
a processor heat exchanger;
a casing configured to be coupled to the processor heat exchanger, the casing comprising an inlet for the working fluid and an outlet for the working fluid, the casing co-operating with the processor heat exchanger to define an internal pump cavity in which heat exchange can occur between the processor heat exchanger and the working fluid as the working fluid passes from the inlet to the outlet;
a rotor mounted for rotation within the internal pump cavity, and
a motor operable to rotate the rotor in order to drive the working fluid through the internal pump cavity from the inlet through the internal pump cavity to the outlet;
wherein the pump is configured so that, in use, the processor heat exchanger lies adjacent, and abuts against, the processor so that heat can pass from the processor to the working fluid in the internal pump cavity as the working fluid is driven by the rotor from the inlet through the internal pump cavity towards the outlet;
and said heat exchange system comprises:
a heat transfer system, said heat transfer system comprising a fan, and a heat exchanger arranged relative to the fan so that the fan is operable to blow or draw air over and/or through the heat exchanger, wherein the fan and the heat exchanger each include a pathway through which the working fluid can flow, the respective pathways being coupled to one another so that the working fluid can flow through the fan and the heat exchanger to enable heat transfer between the working fluid and ambient air.

51. A computing resource comprising a processor, and a processor cooling system for cooling that processor, said processor cooling system comprising a pump, and a heat exchange system fluidly coupled to the pump, the computing resource being arranged such that working fluid warmed by said processor is driven by the pump to and through the heat exchange system for heat transfer with an ambient environment, and thence from the heat exchange system back to the pump, wherein:
said pump comprises:
a processor heat exchanger;
a casing configured to be coupled to the processor heat exchanger, the casing comprising an inlet for the working fluid and an outlet for the working fluid, the casing co-operating with the processor heat exchanger to define an internal pump cavity in which heat exchange can occur between the processor heat exchanger and the working fluid as the working fluid passes from the inlet to the outlet;
a rotor mounted for rotation within the internal pump cavity, and
a motor operable to rotate the rotor in order to drive the working fluid through the internal pump cavity from the inlet through the internal pump cavity to the outlet;
wherein the pump is configured so that, in use, the processor heat exchanger lies adjacent, and abuts against, the processor so that heat can pass from the processor to the working fluid in the internal pump cavity as the working fluid is driven by the rotor from the inlet through the internal pump cavity towards the outlet;
and said heat exchange system comprises:
a heat transfer system, said heat transfer system comprising a fan, and a heat exchanger arranged relative to the fan so that the fan is operable to blow or draw air over and/or through the heat exchanger, wherein the fan and the heat exchanger each include a pathway through which the working fluid can flow, the respective pathways being coupled to one another so that the working fluid can flow through the fan and the heat exchanger to enable heat transfer between the working fluid and ambient air.
